(19) United States
(12) Patent Application Publication
(10) Pub. No.: US 2008/0142824 A1
(43) Pub. Date: Jun. 19, 2008

(54) ELECTROLUMINESCENT DEVICE AND FABRICATION METHOD THEREOF

(76) Inventors: Shih-Peng CHEN, Taoyuan Hsien (TW); Ching-Chuan Shiue, Taoyuan Hsien (TW); Hsueh-Kuo Liao, Taoyuan Hsien (TW); Chuan-Chia Cheng, Taoyuan Hsien (TW); Huang-Kun Chen, Taoyuan Hsien (TW)

Correspondence Address: BIRCH STEWART KOLASCH & BIRCH, PO BOX 747, FALLS CHURCH, VA, 22040-0747, US

(21) Appl. No.: 11/941,799

(22) Filed: Nov. 16, 2007

(30) Foreign Application Priority Data
Dec. 18, 2006 (TW) 095147368

(51) Int. Cl. H01L 33/00; H01L 21/00

(52) U.S. Cl. 257/98; 438/29; 257/E33.001; 257/E21.001

(57) ABSTRACT

An electroluminescent device includes a substrate, a reflection layer, a patterned transparent conductive layer, at least one LED element, a first contact electrode and a second contact electrode. The reflection layer is formed on the substrate. The patterned transparent conductive layer is disposed on the reflection layer. The LED element is formed on the patterned transparent conductive layer and includes a first semiconductor layer, an electroluminescent layer and a second semiconductor layer. The second semiconductor layer is disposed on the patterned transparent conductive layer and the reflection layer. The first contact electrode is electrically connected to the first semiconductor layer. The second contact electrode is electrically connected to the second semiconductor layer.

### CROSS REFERENCE TO RELATED APPLICATIONS

This Non-provisional application claims priority under 35 U.S.C. §119(a) on Patent Application No(s). 095147368, filed in Taiwan, Republic of China on Dec. 18, 2006, the entire contents of which are hereby incorporated by reference.

### BACKGROUND OF THE INVENTION

1. Field of Invention

The invention relates to an electroluminescent device with high efficiency and a fabrication method thereof.

2. Related Art

A light emitting diode (LED) is a cold lighting element, which releases lights when energy released after electrons and holes are combined in a semiconductor material. According to different used materials, various monochromatic lights with different wavelengths are outputted. The LEDs may be mainly classified into a visible light LED and an invisible light (infrared) LED. Compared with the conventional lighting manner of a light bulb or lamp, the LED has advantages of power save, vibration resist, and high flicker speed, so that the LED has become an indispensable and important element in the daily life.

Referring to FIG. 1, a conventional LED device 1 is made by at least one LED element 10 adhered to a transparent substrate 11. The LED element 10 includes a n-type semiconductor layer 101, an electroluminescent layer 102 and a p-type semiconductor layer 103, which are arranged in order, a first contact electrode 104 connected to the n-type semiconductor layer 101 and a second contact electrode 105 connected to the p-type semiconductor layer 103. When voltages are respectively applied to the semiconductor layers 101 and 103 to generate currents, the electrons and the holes of the n-type semiconductor layer 101 and the p-type semiconductor layer 103 are combined together so that electric power is converted into optical energy. In addition, the LED element 10 is adhered to the transparent substrate 11 through a transparent adhesive layer 12. In addition, the junction between the LED element 10 and the transparent adhesive layer 12 further uses a transparent conductive layer 13 in order to enhance the current dispersing efficiency. Thus, the overall lighting luminance of the overall LED device 1 is increased according to the uniform current distribution.

Typically, an epitaxy substrate serves as the transparent substrate 11, and the transparent adhesive layer 12 is composed of an organic adhesive material. Because the thermal conductivity coefficients of the epitaxy substrate and the organic adhesive material are low, a better heat dissipating path for the LED element 10 cannot be provided. Thus, the accumulated heat generated when the LED device 1 is operating cannot be easily dissipated, and the lighting efficiency of the LED device 1 is influenced.

Because the development of the LED in the current stage still has the problem of too-low lighting efficiency, the manufacturers have paid their attention to take out the photons generated in the LED element 10 effectively, and to reduce the nonessential heat generated by the continuous reflection of the photons in the LED element 10. On the other hand, the manufacturers also pay their attention to solve the problem of the heat dissipation in the LED element 10 so that the operating temperature of the overall LED device 1 can be lowered, and the lighting efficiency of the LED device 1 can be finally enhanced.

### SUMMARY OF THE INVENTION

In view of the foregoing, the present invention is to provide an electroluminescent device and a fabrication method thereof capable of effectively enhancing the current dispersing efficiency and effectively reducing the heat.

To achieve the above, the present invention discloses a fabrication method for an electroluminescent device. The fabrication method includes the steps of providing a plate, forming at least one light emitting diode (LED) element on the plate, forming a patterned transparent conductive layer on the LED element, forming a reflection layer on the patterned transparent conductive layer, adhering a substrate to the reflection layer, and removing the plate. Herein, the LED element includes a first semiconductor layer, an electroluminescent layer and a second semiconductor layer arranged in order, and the first semiconductor layer is formed on the plate.

To achieve the above, the present invention also discloses an electroluminescent device including a substrate, a reflection layer, at least one LED element, a first contact electrode and a second contact electrode. The reflection layer is formed on the substrate, and the patterned transparent conductive layer is disposed on the reflection layer. The LED element is formed on the patterned transparent conductive layer and includes a first semiconductor layer, an electroluminescent layer and a second semiconductor layer arranged in order. The second semiconductor layer is disposed on the patterned transparent conductive layer and the reflection layer. The first contact electrode is electrically connected to the first semiconductor layer. The second contact electrode is electrically connected to the second semiconductor layer.

As mentioned above, the electroluminescent device and the fabrication method thereof according to the present invention have the following features. Firstly, a patterned transparent conductive layer, which may be formed with a plurality of island patterns by way of, for example, etching, is provided in the electroluminescent device. Thus, an LED element may have a uniform current distribution due to the patterns of the patterned transparent conductive layer so that the current blocking phenomenon can be effectively avoided. In addition, the reflection layer is provided so that a good ohmic contact between the patterned transparent conductive layer and the reflection layer is formed, and an interface for scattering and reflecting light is provided so that the external light acquiring and lighting efficiency can be effectively enhanced. In addition, the substrate and the reflection layer have the high thermal conductivity, the heat dissipation of the LED element can be enhanced more effectively as compared with the prior art.

### BRIEF DESCRIPTION OF THE DRAWINGS

The invention will become more fully understood from the detailed description given herein below illustration only, and thus is not limitative of the present invention, and wherein:

FIG. 1 is a schematic illustration showing a conventional LED device;

FIGS. 2A to 7B are schematic illustrations showing an electroluminescent device according to the preferred embodiment of the present invention;

FIG. 8 is a flow chart showing a fabrication method of the electroluminescent device according to the preferred embodiment of the present invention; and

FIGS. 9A and 9B are schematic illustrations showing the fabrication method of the electroluminescent device according to the preferred embodiment of the present invention.

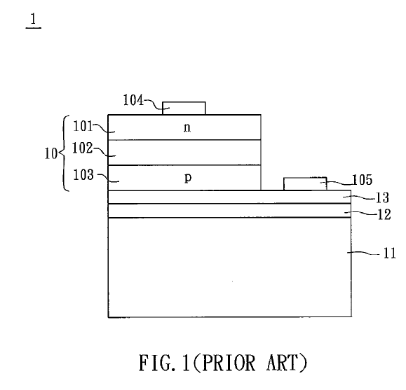

### DETAILED DESCRIPTION OF THE INVENTION

The present invention will be apparent from the following detailed description, which proceeds with reference to the accompanying drawings, wherein the same references relate to the same elements.

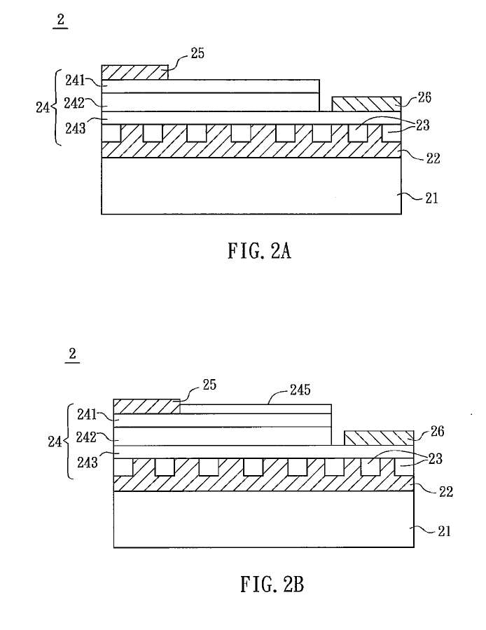

Referring to FIGS. 2A to 5C, an electroluminescent device 2 according to a preferred embodiment of the invention includes a substrate 21, a reflection layer 22, a patterned transparent conductive layer 23, at least one LED element 24, a first contact electrode 25 and a second contact electrode 26.

In this embodiment, the substrate 21 has a high thermal conductivity coefficient and is made of the material selecting from one of the group consisting of silicon (Si), gallium arsenide (GaAs), gallium phosphide (GaP), silicon carbide (SiC), boron nitride (BN), aluminum nitride (AlN), aluminum (Al), copper (Cu) and combinations thereof.

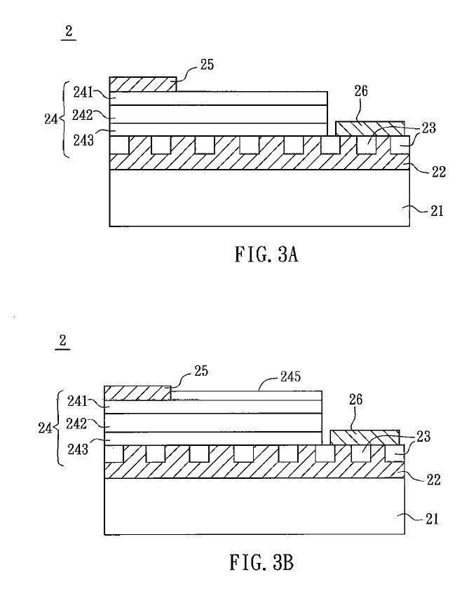

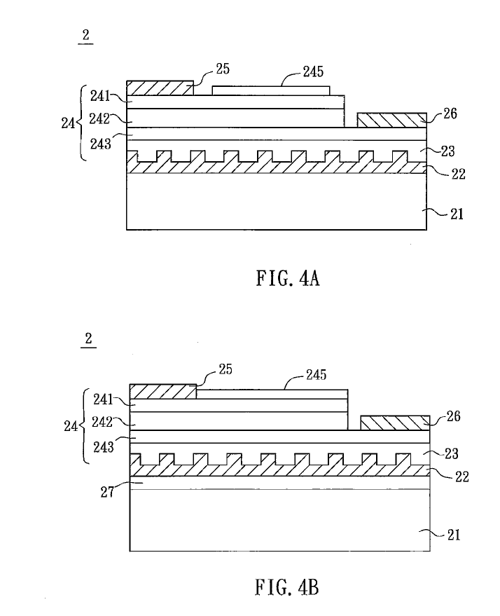

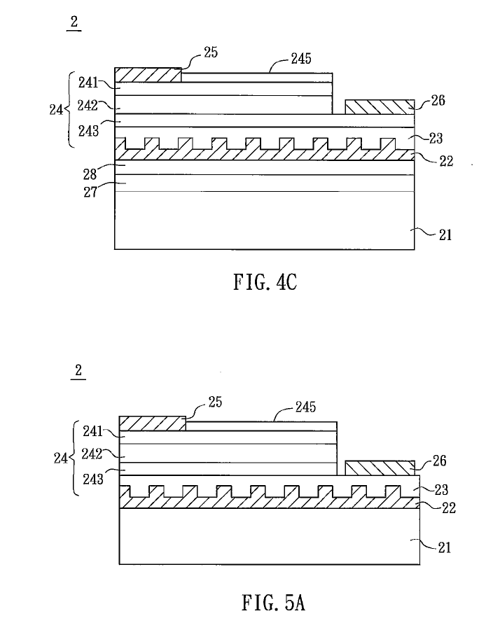

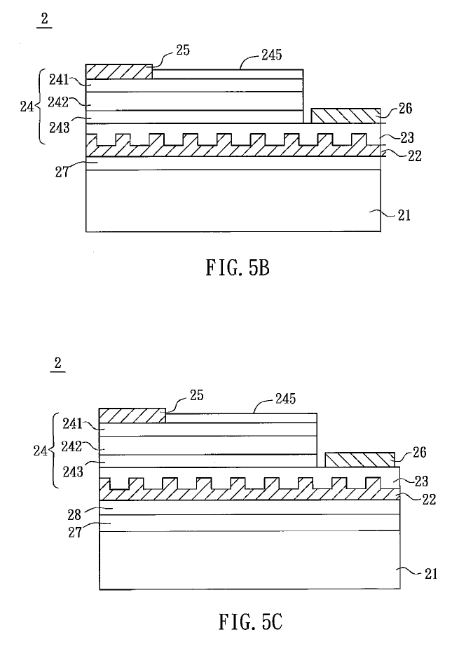

The reflection layer 22 is formed on the substrate 21, and the patterned transparent conductive layer 23 is disposed on the reflection layer 22. As shown in FIGS. 2A to 5C, the reflection layer 22 has a concave-convex surface, and the concave portions of the patterned transparent conductive layer 23 are full with the reflection layer 22 so that the patterned transparent conductive layer 23 is formed to include a plurality of independent or continuous island patterns. That is, the island patterns may be separated into individual island structures, as shown in FIGS. 2A and 3A. In addition, the island patterns may have continuous island structures, as shown in FIGS. 4A and 5A. Of course, the patterned transparent conductive layer 23 may also be composed of the above-mentioned two island structures. Each island pattern has a cross-section with a rectangular shape, a circular shape, a polygonal shape or an irregular shape.

In this embodiment, the material of the reflection layer 22 is a material with high reflectivity, and the concave-convex surface of the reflection layer 22 provides good light reflecting and scattering effects so that external light acquiring efficiency can be enhanced. The reflection layer 22 may be made of platinum (Pt), gold (Au), silver (Ag), palladium (Cr), nickel (Ni), platinum (Pd), titanium (Ti), aluminum (Al) or combinations thereof. In addition, a good ohmic contact is formed through the connection between the reflection layer 22 and the transparent conductive layer 23 in this embodiment so that the resistance value can be reduced and the lighting efficiency of the electroluminescent device 2 can be thus increased. Further, the transparent conductive layer 23 also serves as a bonding layer, as shown in FIGS. 2A, 2B, 3A, 3B, and 5A, 6A. (14A)

The LED element 24 is formed on the patterned transparent conductive layer 23 and includes a first semiconductor layer 241, an electroluminescent layer 242 and a second semiconductor layer 243. The second semiconductor layer 243, the electroluminescent layer 242 and the first semiconductor layer 241 are sequentially formed on the patterned transparent conductive layer 23 and the reflection layer 22. In this embodiment, the LED element 24 may be formed on the patterned transparent conductive layer 23 with independent island patterns. Herein, the second semiconductor layer 243 is in contact with the patterned transparent conductive layer 23 and the reflection layer 22, as shown in FIGS. 2A and 3A. In addition, the LED element 24 may also be formed on the patterned transparent conductive layer 23 with the continuous island patterns. Herein, the second semiconductor layer 243 is in contact with the patterned transparent conductive layer 23, as shown in FIGS. 4A and 5A. The effective and homogeneous current distribution of the LED element 24 is achieved according to the pattern of the patterned transparent conductive layer 23, and the phenomenon of current blocking can be avoided.

As mentioned hereinabove, the first semiconductor layer 241 is an n-type semiconductor layer and the second semiconductor layer 243 is a p-type semiconductor layer in this non-limitative embodiment. Of course, the first semiconductor layer 241 and the second semiconductor layer 243 may be the applications of the n-type semiconductor layer and the p-type semiconductor layer, and may be exchanged according to the actual requirement.

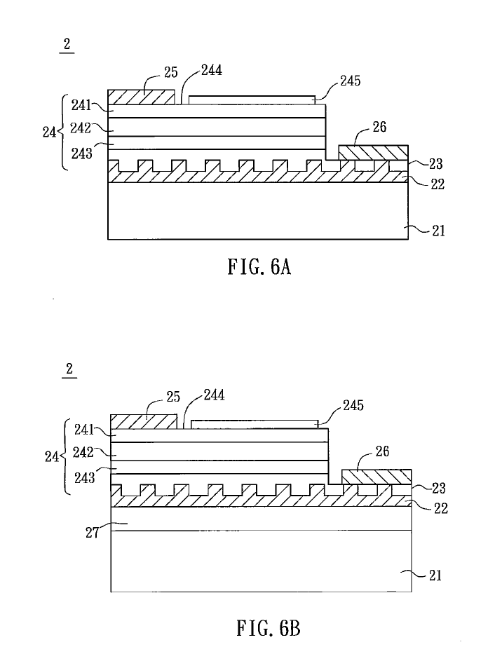

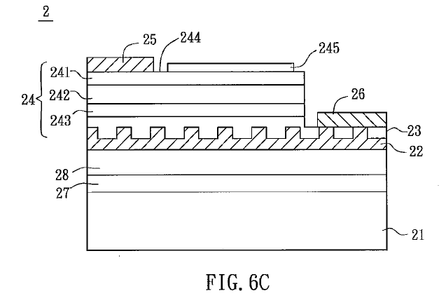

The first contact electrode 25 is electrically connected to the first semiconductor layer 241, and the second contact electrode 26 is electrically connected to the second semiconductor layer 243. Descriptions will be made in detail according to an example, in which the first contact electrode 25 and the second contact electrode 26 are located at the same side of the substrate 21. As shown in FIGS. 2A and 4A, the first contact electrode 25 is formed on the first semiconductor layer 241, and the second contact electrode 26 is formed on the second semiconductor layer 243. In addition, a portion of the second semiconductor layer 243 may be etched according to the actual requirement to expose a portion of the patterned transparent conductive layer 23 and/or the reflection layer 22, as shown in FIGS. 3A and 5A. Herein, the second contact electrode 26 may be formed on the patterned transparent conductive layer 23 with the independent island patterns and on the reflection layer 22, as shown in FIG. 3A, or the second contact electrode 26 may be formed on the patterned transparent conductive layer 23 with the continuous island patterns, as shown in FIG. 5A. In addition to the etching of a portion of the second semiconductor layer 243, when the patterned transparent conductive layer 23 has the continuous island patterns, a portion of the patterned transparent conductive layer 23 may further be etched, and the second contact electrode 26 is formed on the patterned transparent conductive layer 23 and/or the reflection layer 22, as shown in FIG. 6A.

In addition to the first contact electrode 25 formed on the first semiconductor layer 241, a rough structure or an anti-reflection layer 245 may be disposed on a light outputting surface 244 of the LED element 24 (i.e., on a position at the side of the first semiconductor layer 241 without the first contact electrode 25) for guiding out lights so as to effectively enhance light outputting efficiency, as shown in FIGS. 2B and 3B. Also, in addition to the structures, in which the conductive substrate 21 may be directly in contact with the reflection layer 22, as shown in FIGS. 4A, 5A and 6A, an adhesive layer 27 with high thermal conductivity may be added and disposed between the substrate 21 and the reflection layer 22, as shown in FIGS. 4B, 5B and 6B. The material of the adhesive layer 27 may be a silver paste, a tin paste, a tin-silver paste, or any other conductive adhesive material, such as alloy, metal or an eutectic bonding material, and may include a leaded or unleaded conductive adhesive material. The thermal conductivity coefficient of the material of the adhesive layer 27 in this embodiment is higher than that of the typically used organic adhesive material, so the object of heat dissipation can be achieved more effectively.

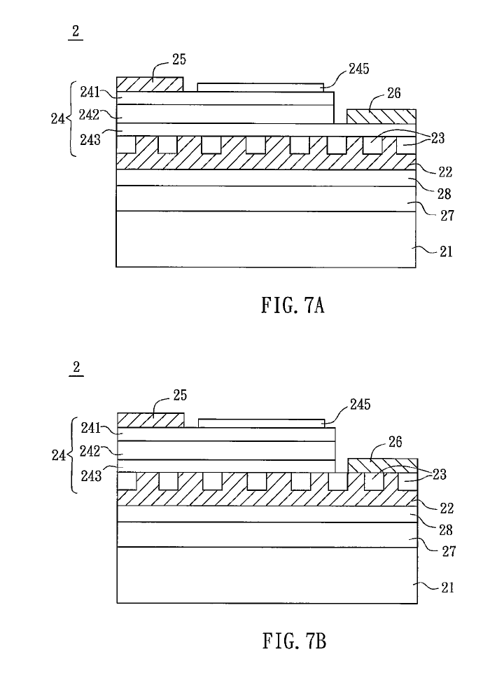

In addition, as shown in FIGS. 4C, 5C and 6C, when the substrate 21 is a conductive substrate, the electroluminescent device 2 of this embodiment may further include an insulating layer 28 disposed between the adhesive layer 27 and the reflection layer 22 in order to prevent the LED element 24 from being directly electrically connected to the substrate 21. In order to achieve the better radiation effect, the insulating layer 28 of this embodiment may be made of an insulating material having a high thermal conductivity coefficient such as aluminum nitride or silicon carbide. Also, as shown in FIG. 7A, the second contact electrode 26 is formed on the second semiconductor layer 243. In addition, the second semiconductor layer 243 may also be further removed, and the second contact electrode 26 is then formed on the patterned transparent conductive layer 23 and/or the reflection layer 22, as shown in FIG. 7B.

As mentioned hereinabove, the electroluminescent device 2 of this embodiment uses the insulating layer 28, the adhesive layer 27 and the substrate 21, each of which has characteristic of high thermal conductivity coefficient, so that the operating temperature of the LED element 24 can be sufficiently decreased. Also, the electroluminescent device 2 has the advantages of withstanding high current and may be fabricated to have a large area so that the overall lighting efficiency of the electroluminescent device 2 is greatly enhanced.

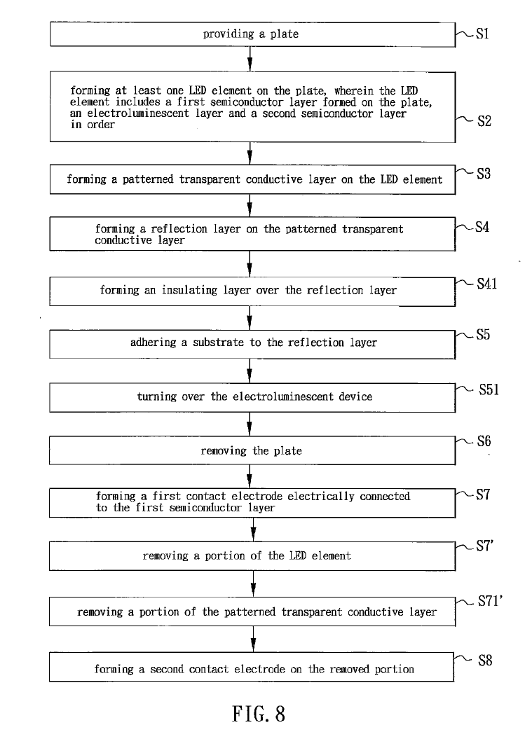

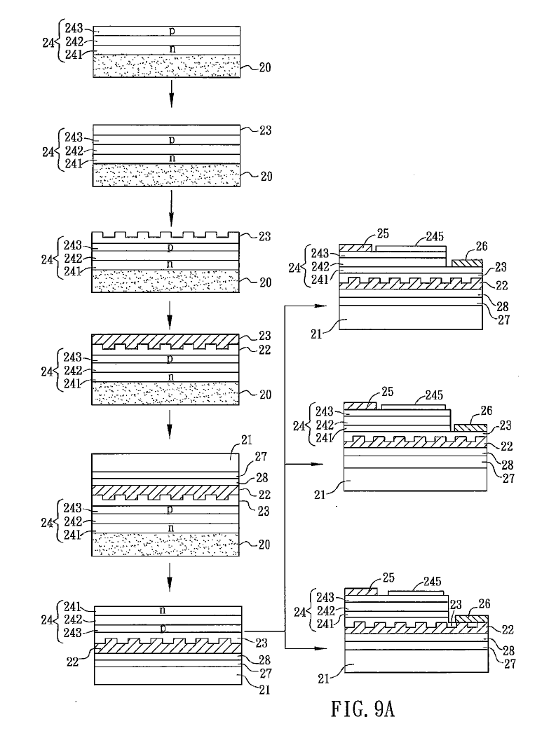

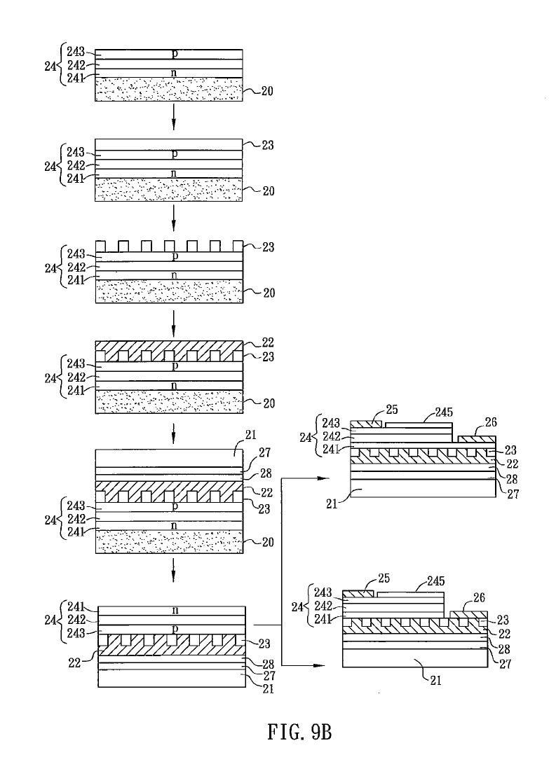

In order to make the content of the electroluminescent device 2 of the present invention clearer, the fabrication method of the electroluminescent device according to the preferred embodiment of the invention will be described with reference to FIGS. 8, 9A and 9B. The fabrication method includes steps S1 to S6. In the step S1, a plate 20 is provided. In the step S2, at least one LED element 24 is formed on the plate 20. The LED element 24 includes a first semiconductor layer 241, an electroluminescent layer 242 and a second semiconductor layer 243 arranged in order. The first semiconductor layer 241 is formed on the plate 20. In the step S3, a patterned transparent conductive layer 23 is formed on the LED element 24. In the step S4, a reflection layer 22 is formed on the patterned transparent conductive layer 23. In the step S5, a substrate 21 is adhered to the reflection layer 22. In the step S6, the plate 20 is removed.

In the step S1, the plate 20 is provided. The plate 20 is a temporary plate used when the LED element 24 is being fabricated. The material of the plate 20 includes, for example, aluminum oxide (Al₂O₃). After the plate 20 is properly cleaned, the epitaxial layer growth of the LED element 24 may be performed subsequently.

In the step S2, the LED element 24 is formed on the plate 20. That is, the first semiconductor layer 241, the electroluminescent layer 242 and the second semiconductor layer 243 sequentially grow on the plate 20. In this non-limitative embodiment the first semiconductor layer 241 may be an n-type semiconductor layer, and the second semiconductor layer 243 may be a p-type semiconductor layer.

In the step S3, the patterned transparent conductive layer 23 is formed on the LED element 24. In this embodiment, a material, such as indium tin oxide, cadmium tin oxide, antimomy tin oxide, beryllium (Be), germanium (Ge), nickel (Ni), aurum (Au) or combinations thereof, is deposited on the second semiconductor layer 243 of the LED element 24. Then, the deposited material is patterned using a photo lithography process and an etching process, wherein the etching process may be implemented by using dry-etching or wet-etching process in conjunction with the physical etching and/or chemical etching processes. In this embodiment, the patterned transparent conductive layer 23 may include a plurality of island patterns. The etching step may be terminated according to different etching depths. For example, the etching step may be terminated on a position of the patterned transparent conductive layer 23 with an arbitrary depth so that the patterned transparent conductive layer 23 has the continuous island pattern structures, as shown in FIG. 9A. In addition, the etching step may be terminated on the second semiconductor layer 243 of the LED element 24 after the overall patterned transparent conductive layer 23 has been etched through so that the patterned transparent conductive layer 23 has the independent island pattern structures, as shown in FIG. 9B. The island pattern is not particularly restricted, and each island pattern has a cross-section with a rectangular shape, a circular shape, a polygonal shape or an irregular shape.

In the step S4, the reflection layer 22 is formed on the patterned transparent conductive layer 23. In this embodiment, a material with high reflectivity such as platinum (Pt), aurum (Au), silver (Ag), Chromium (Cr), nickel (Ni), palladium (Pd), titanium (Ti), aluminum (Al) or combinations thereof, is deposited on the patterned transparent conductive layer 23. The reflection layer 22 formed on the patterned transparent conductive layer 23 has a concave-convex surface according to the patterned structure of the patterned transparent conductive layer 23 and is in ohmic contact with the patterned transparent conductive layer 23. Thus, the overall lighting efficiency can be effectively enhanced by increasing the external light acquiring efficiency and decreasing the resistance value.

The fabrication method may further include a step S41 after the step S4. In the step S41, an insulating layer 28 is formed over the reflection layer 22. In this embodiment the material of the insulating layer 28 is an insulating with a high thermal conductivity coefficient, such as aluminum nitride or silicon carbide, and the insulating layer 28 is formed over the reflection layer 22 by way of reactive sputtering, non-reactive sputtering, high-temperature nitriding and high-temperature powder sintering.

In the step S5, the substrate 21 is adhered to the reflection layer 22. In this embodiment, the substrate 21 is adhered to the insulating layer 28 through an adhesive layer 27. Herein, the adhesive layer 27 may be coated on the reflection layer 22/insulating layer 28 or the substrate 21, and then the substrate 21 is adhered to the insulating layer 28. In addition, the adhesive layer 27 may partially cover or completely cover the surface of the reflection layer 22/insulating layer 28. Each of the substrate 21 and the adhesive layer 27 has high thermal conductivity, and the material of the substrate 21 is selected from at least one of the group consisting of silicon (Si), gallium arsenide (GaAs), gallium phosphide (GaP), silicon carbide (SiC), Boron Nitride (BN), aluminum nitride (AlN), aluminum (Al), copper (Cu) and combinations thereof The material of the adhesive layer 27 may be a silver paste, a tin paste, a tin-silver paste, or any other conductive adhesive material, such as alloy, metal or a eutectic bonding material, and may include a leaded or unleaded conductive adhesive material.

The fabrication method may further include, after the step S5, a step S51 of turning over the electroluminescent device to remove the temporary plate subsequently.

In the step S6, the temporary plate 20 for the growth of the LED element 24 is removed. In this embodiment, the step of turning over the electroluminescent device may be performed after the step S6.

The fabrication method may further include, after the step S6, a step S7 of forming a first contact electrode 25 electrically connected to the first semiconductor layer 241. In this embodiment, the first contact electrode 25 is formed on one side of the first semiconductor layer 241. In the step S7, a rough structure or an anti-reflection layer 245 is formed on a position at the side of the first semiconductor layer 241 without the first contact electrode 25 so that the opportunity of guiding out the light may be increased.

In addition, the fabrication method may further include, after the step S6, a step S7′ of removing a portion of the LED element 24, as shown in FIGS. 9A and 9B. A second contact electrode 26 may be formed on the second semiconductor layer 243 after a portion of first semiconductor layer 241 and a portion of the electroluminescent layer 242 are removed. In addition, the second semiconductor layer 243 may further be removed, and then the second contact electrode 26 is formed on the patterned transparent conductive layer 23 and/or the reflection layer 22. In other words, the second contact electrode 26 is formed on the removed portion (step S8) after the portions of the LED element 24 with different depths are removed, and the second contact electrode 26 is electrically connected to the second semiconductor layer 243.

In addition, the fabrication method may further include, after the step S7′, a step S71′ of removing a portion of the patterned transparent conductive layer 23 according to different island patterns of the patterned transparent conductive layer 23. Then, the second contact electrode 26 is formed on the removed portion (step S8), and electrically connected to the second semiconductor layer 243.

In summary, the electroluminescent device and the fabrication method thereof according to the invention have the following features. Firstly, a patterned transparent conductive layer, which may be formed with a plurality of island patterns by way of, for example, etching, is provided in the electroluminescent device. Thus, an LED element may have a uniform current distribution due to the patterns of the patterned transparent conductive layer so that the current blocking phenomenon can be effectively avoided. Also, the reflection layer is provided so that a good ohmic contact between the patterned transparent conductive layer and the reflection layer is formed, and an interface for scattering and reflecting light is provided so that the external light acquiring and lighting efficiency can be effectively enhanced. In addition, the substrate and the reflection layer have high thermal conductivity, the heat dissipation of the LED element can be enhanced more effectively as compared with the prior art.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A fabrication method for an electroluminescent device, comprising steps of:
providing a plate;
forming at least one light emitting diode (LED) element on the plate, wherein the LED element comprises a first semiconductor layer, an electroluminescent layer and a second semiconductor layer arranged in order, and the first semiconductor layer is formed on the plate;
forming a patterned transparent conductive layer on the LED element;
forming a reflection layer on the patterned transparent conductive layer;
adhering a substrate to the reflection layer; and
removing the plate.

2. The fabrication method according to claim 1, wherein after the step of removing the plate, the method further comprises a step of:
forming a first contact electrode at one side of the first semiconductor layer and being electrically connected to the first semiconductor layer, and a rough structure or an anti-reflection layer is formed on a position at the side of the first semiconductor layer with the first contact electrode.

3. The fabrication method according to claim 1, wherein after the step of removing the plate, the method further comprises steps of:
removing a portion of the LED element;
removing a portion of the patterned transparent conductive layer; and
forming a second contact electrode on the removed portion, wherein the second contact electrode is electrically connected to the second semiconductor layer.

4. The fabrication method according to claim 3, wherein a portion of the first semiconductor layer and the electroluminescent layer are removed, or a portion of the second semiconductor layer is removed.

5. The fabrication method according to claim 1, after the step of forming the reflection layer on the patterned transparent conductive layer, the method further comprising a step of:
forming an insulating layer over the reflection layer, wherein the insulating layer is formed on the reflection layer by way of reactive sputtering, non-reactive sputtering, high-temperature nitriding and high-temperature powder sintering.

6. The fabrication method according to claim 1, wherein the patterned transparent conductive layer comprises a plurality of island patterns, the island patterns are independent or continuous, and each island pattern has a cross-section with a rectangular shape, a circular shape, a polygonal shape or an irregular shape.

7. An electroluminescent device, comprising:
a substrate;
a reflection layer formed on the substrate;
a patterned transparent conductive layer disposed on the reflection layer;
at least one LED element, which is formed on the patterned transparent conductive layer and comprises a first semiconductor layer, an electroluminescent layer and a second semiconductor layer arranged in order, wherein the second semiconductor layer is disposed on the patterned transparent conductive layer and the reflection layer;
a first contact electrode electrically connected to the first semiconductor layer; and
a second contact electrode electrically connected to the second semiconductor layer.

8. The electroluminescent device according to claim 7, wherein the reflection layer is an Ohmic contact metal layer, and the reflection layer comprises platinum, gold, silver, palladium, nickel, platinum, titanium, aluminum or combinations thereof.

9. The electroluminescent device according to claim 7, wherein the reflection layer has a concave-convex surface.

10. The electroluminescent device according to claim 9, wherein the patterned transparent conductive layer is filled in concave portions of the concave-convex surface of the reflection layer.

11. The electroluminescent device according to claim 7, wherein the patterned transparent conductive layer comprises a plurality of island patterns.

12. The electroluminescent device according to claim 11, wherein the island patterns are independent or continuous, and each island pattern has a cross-section with a rectangular shape, a circular shape, a polygonal shape or an irregular shape.

13. The electroluminescent device according to claim 7, further comprising an adhesive layer disposed between the substrate and the reflection layer.

14. The electroluminescent device according to claim 13, wherein each of the substrate and the adhesive layer has high thermal conductivity.

15. The electroluminescent device according to claim 14, wherein the substrate comprises silicon, gallium arsenide, gallium phosphide, silicon carbide, boron nitride, aluminum nitride, aluminum, copper or combinations thereof, and the adhesive layer comprises a silver paste, a tin paste, a tin-silver paste, or a conductive adhesive material.

16. The electroluminescent device according to claim 13, further comprising an insulating layer disposed between the adhesive layer and the reflection layer.

17. The electroluminescent device according to claim 16, wherein a material of the insulating layer is aluminum nitride or silicon carbide.

18. The electroluminescent device according to claim 7, wherein the first contact electrode is formed on the first semiconductor layer.

19. The electroluminescent device according to claim 18, wherein a rough structure or an anti-reflection layer is formed on a position at the side of the first semiconductor layer with the first contact electrode.

20. The electroluminescent device according to claim 7, wherein the second contact electrode is formed on the second semiconductor layer, or the second contact electrode is formed on the patterned transparent conductive layer and the reflection layer.
